(19) United States
(12) Patent Application Publication
(10) Pub. No.: US 2013/0125957 A1
(43) Pub. Date: May 23, 2013

(54) PHOTOELECTRIC CONVERSION DEVICE

(71) Applicants: Hyun-Chul KIM, Yongin-si (KR); Jong-Ki Lee, Yongin-si (KR)

(72) Inventors: Hyun-Chul KIM, Yongin-si (KR); Jong-Ki Lee, Yongin-si (KR)

(21) Appl. No.: 13/588,537

(22) Filed: Aug. 17, 2012

(30) Foreign Application Priority Data
Nov. 18, 2011 (KR) 10-2011-0121189

(51) Int. Cl. H01L 31/0224; H01L 31/048

(52) U.S. Cl. 136/251; 136/256

(57) ABSTRACT

A photoelectric conversion device including a first substrate; a first electrode on the first substrate and including a grid pattern; a second substrate facing the first substrate; a second electrode on the second substrate; a semiconductor layer on the first substrate at an opening region of the grid pattern; and a conductive thin film on the first substrate between the grid pattern and the semiconductor layer.

### CROSS-REFERENCE TO RELATED APPLICATION

This application claims priority to and the benefit of Korean Patent Application No. 10-2011-0121189, filed on Nov. 18, 2011 in the Korean Intellectual Property Office, the entire content of which is incorporated herein by reference.

### BACKGROUND

1. Field

Aspects of embodiments of the present invention relate to a photoelectric conversion device.

2. Description of the Related Art

Recently, research has been conducted on various photoelectric conversion devices for converting light energy into electric energy as an energy source for replacing fossil fuel, and solar batteries for obtaining energy from sunlight are attracting attention.

From among solar batteries having various operation principles, wafer-type silicon or crystalline solar batteries using p-n junctions of semiconductors are the most popular but require high manufacturing costs to form and process high purity semiconductor materials.

Unlike a silicon solar battery, a dye-sensitive solar battery mainly includes a photosensitive dye that receives light having a wavelength of visible light and generates excited electrons, a semiconductor material that receives the excited electrons, and an electrolyte that reacts with electrons returning from an external circuit. The dye-sensitive solar battery has much higher efficiency of photoelectric conversion than general solar batteries and thus is regarded as a next-generation solar battery.

### SUMMARY

According to an aspect of embodiments of the present invention, a photoelectric conversion device forms a low-resistance current path and improves the overall efficiency of photoelectric conversion.

Additional aspects of embodiments of the present invention are set forth, in part, in the description which follows and, in part, will be apparent from the description, or may be learned by practice of the presented embodiments.

According to an embodiment of the present invention, a photoelectric conversion device includes; a first substrate; a first electrode on the first substrate and including a grid pattern; a second substrate facing the first substrate; a second electrode on the second substrate; a semiconductor layer on the first substrate at an opening region of the grid pattern; and a conductive thin film on the first substrate between the grid pattern and the semiconductor layer.

The first electrode may further include a transparent conductive film between the first substrate and the grid pattern.

The grid pattern, the semiconductor layer, and the conductive thin film may be formed together on the transparent conductive film.

The photoelectric conversion device may further include a protective layer covering an outer surface of the grid pattern.

The protective layer may cover the grid pattern so as to contact the conductive thin film.

The grid pattern may include a plurality of finger electrodes extending in parallel along a first direction; and a collecting electrode extending in a second direction crossing the first direction and interconnecting end portions of the finger electrodes.

The grid pattern may have a comb shape in which the finger electrodes protrude from the collecting electrode at substantially equal intervals along the second direction.

The conductive thin film may extend in a repeated bent pattern along the finger electrodes and the collecting electrode.

The grid pattern may have a comb shape in which the finger electrodes protrude from the collecting electrode at substantially equal intervals along the second direction, and the semiconductor layer may have a comb shape that is complementary to the comb shape of the grid pattern.

The conductive thin film may include titanium (Ti).

The photoelectric conversion device may further include an electrolyte between the first and second substrates; and sealing members extending to surround the electrolyte between the first and second substrates.

The sealing members may partition a plurality of photoelectric cells between the first and second substrates, and the photoelectric conversion device may further include a connection member between the sealing members and electrically connecting neighboring photoelectric cells of the plurality of photoelectric cells to each other.

The conductive thin film may extend toward the connection member.

The conductive thin film between the grid pattern and the semiconductor layer may extend toward and contact the connection member.

According to another embodiment of the present invention, a photoelectric conversion device includes: first and second substrates facing each other; sealing members partitioning a plurality of photoelectric cells between the first and second substrates; and a connection member between neighboring sealing members and electrically connecting neighboring photoelectric cells of the plurality of photoelectric cells to each other, each of the plurality of photoelectric cells including a first electrode on the first substrate and including a grid pattern; a second electrode on the second substrate; a semiconductor layer on the first substrate at an opening region of the grid pattern; and a conductive thin film on the first substrate between the grid pattern and the semiconductor layer, and the conductive thin film extends toward and contacts the connection member.

Each of the sealing members may include a spacer on at least one of the first substrate or the second substrate; and a sealant surrounding at least a portion of the spacer.

The connection member may include first and second conductive bumps respectively formed on the first and second substrates; and a flexible conductor connecting the first and second conductive bumps.

### BRIEF DESCRIPTION OF THE DRAWINGS

The above and other aspects of embodiments of the present invention will become more readily apparent from the following description of some exemplary embodiments, taken in conjunction with the accompanying drawings thereof, of which:

FIG. 1 is an exploded perspective view of a photoelectric conversion device according to an embodiment of the present invention;

FIG. 2 is an exploded perspective view of a grid pattern, a semiconductor layer, and a conductive thin film of the photoelectric conversion device of FIG. 1;

FIG. 3 is a top view showing an opening region of the grid pattern of the photoelectric conversion device of FIGS. 1 and 2;

FIG. 4 is a top view showing the alignment of the grid pattern and the semiconductor layer of the photoelectric conversion device of FIGS. 1 and 2;

FIG. 5 is a cross-sectional view of the photoelectric conversion device of FIG. 1, taken along the line V-V;

FIG. 6 is a cross-sectional view of a photoelectric conversion device according to another embodiment of the present invention;

FIG. 7 is a top view of a photoelectric conversion device according to another embodiment of the present invention;

FIG. 8 is a cross-sectional view of the photoelectric conversion device of FIG. 7, taken along the line VIII-VIII;

FIG. 9 is an enlarged view of a region of the cross-sectional view of FIG. 8; and

FIG. 10 is a cross-sectional view of a photoelectric conversion device according to another embodiment of the present invention.

### DETAILED DESCRIPTION

In the following detailed description, some exemplary embodiments of the present invention are shown and described, by way of illustration. As those skilled in the art would realize, the described embodiments may be modified in various different ways, all without departing from the spirit or scope of the present invention.

Accordingly, the drawings and description are to be regarded as illustrative in nature and not restrictive. As used herein, the term “and/or” includes any and all combinations of one or more of the associated listed items.

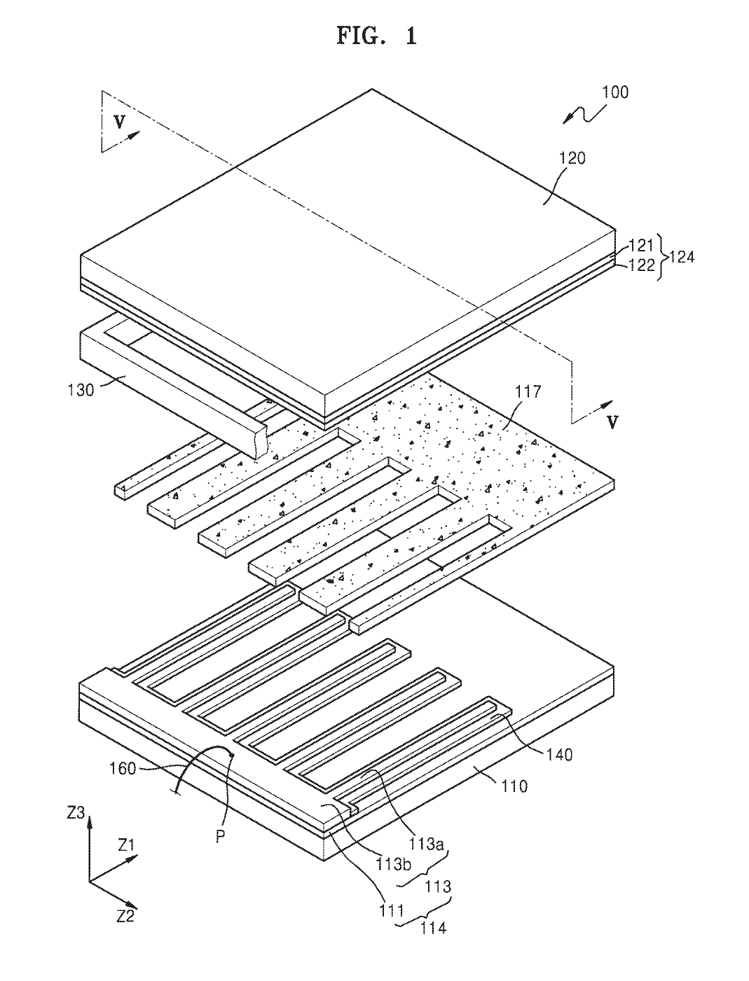

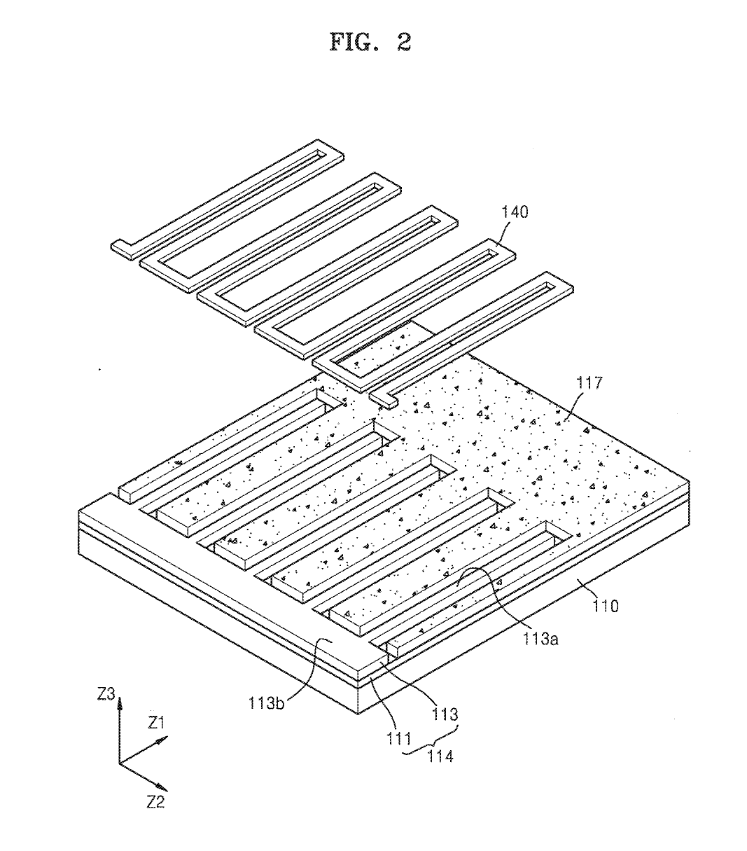

FIGS. 1 and 2 are exploded perspective views of a photoelectric conversion device 100 according to an embodiment of the present invention.

In the photoelectric conversion device 100, a first substrate 110 on which a first electrode 114 is formed and a second substrate 120 on which a second electrode 124 is formed face each other, and a sealing member 130 is disposed between the first and second substrates 110 and 120. The first electrode 114 includes a transparent conductive film 111 and a grid pattern 113 disposed on the first substrate 110. A semiconductor layer 117 is formed on the transparent conductive film 111 exposed by the grid pattern 113.

In one embodiment, the grid pattern 113 includes a plurality of finger electrodes 113a extending in parallel along a direction (e.g., a direction Z1) in a stripe pattern, and a collecting electrode 113b extending in a direction crossing the finger electrodes 113a to interconnect end portions of the finger electrodes 113a, such as along a direction perpendicular to the finger electrodes 113a (e.g., a direction Z2). In one embodiment, excited electrons generated by the semiconductor layer 117 are received by the collecting electrode 113b via the finger electrodes 113a and may be supplied to an external circuit (not shown) via the collecting electrode 113b, thereby forming a driving current.

A contact point P connecting the external circuit may be formed on the collecting electrode 113b and may be connected to a wire 160 extending toward the external circuit. At least a portion of the collecting electrode 113b (e.g., a portion where the contact point P is formed) may be formed outside the sealing member 130. The sealing member 130 extends along edges of the first and second substrates 110 and 120 and seals an electrolyte (not shown) that is contained between the first and second substrates 110 and 120.

In one embodiment, the grid pattern 113 may include the finger electrodes 113a protruding in one direction (e.g., a direction Z1) at equal intervals along a lengthwise direction of the collecting electrode 113b (e.g., a direction Z2) and may generally have an overall comb shape. However, embodiments of the present invention are not limited thereto.

The semiconductor layer 117 is formed on the transparent conductive film 111 in an opening region of the grid pattern 113 exposed by the grid pattern 113. In one embodiment, for example, the semiconductor layer 117 may have a generally overall comb shape that is complementary to that of the grid pattern 113. However, embodiments of the present invention are not limited thereto.

As will be described further below, the semiconductor layer 117 formed in the opening region exposed by the grid pattern 113, or a photosensitive dye (not shown) absorbed into the semiconductor layer 117, may generate excited electrons by using light incident through the opening region as an excitation source.

A conductive thin film 140 is formed between the grid pattern 113 and the semiconductor layer 117. In one embodiment, as illustrated in FIG. 2, the conductive thin film 140 may have a bent pattern between the grid pattern 113 and the semiconductor layer 117 having comb shapes complementary to each other. For example, the conductive thin film 140 may extend along the grid pattern 113 and may be formed in a bent pattern along the finger electrodes 113a and the collecting electrode 113b. The conductive thin film 140 may be formed on the transparent conductive film 111 between the grid pattern 113 and the semiconductor layer 117 and may provide a low-resistance current path by supplementing a relatively low electrical conductivity of the transparent conductive film 111.

In one embodiment, the grid pattern 113, the semiconductor layer 117, and the conductive thin film 140 may entirely cover an upper surface of the transparent conductive film 111 on the first substrate 110 and may be formed on the transparent conductive film 111 so as to supplement the electrical conductivity of the transparent conductive film 111.

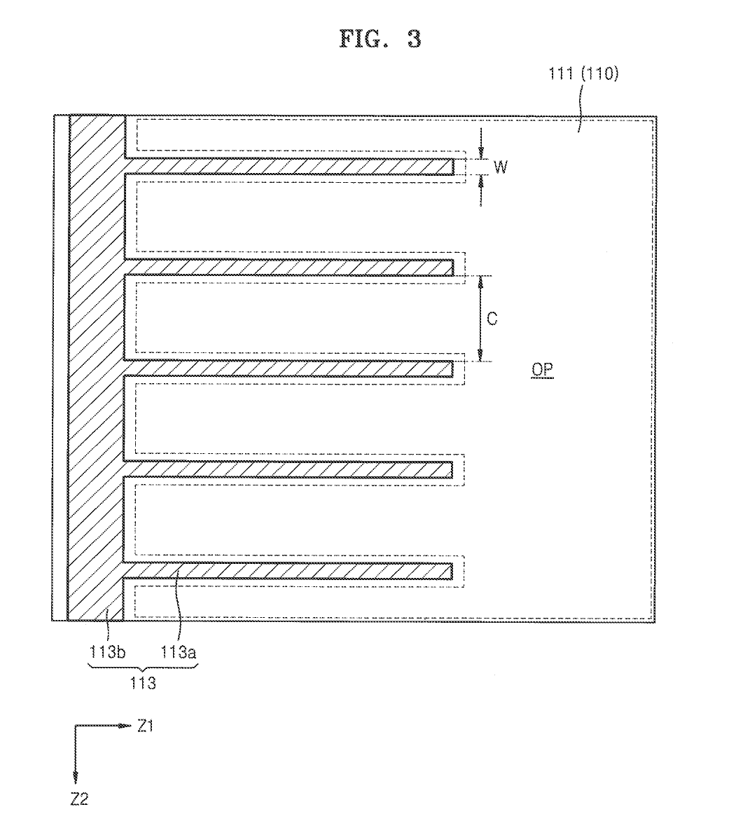

FIG. 3 is a top view showing an opening region OP of the grid pattern 113 illustrated in FIGS. 1 and 2. As illustrated in FIG. 3, the grid pattern 113 may have a comb shape in which the finger electrodes 113a protrude at equal or substantially equal intervals along the collecting electrode 113b.

The grid pattern 113, in one embodiment, may be formed of an opaque metallic material having a relatively high electrical conductivity and may have a suitable opening ratio to increase an amount of received incident light. For example, an appropriate opening ratio may be ensured by adjusting a line width W or a pitch C (i.e. a distance between neighboring finger electrodes 113a) of the finger electrodes 113a formed in a region of the grid pattern 113 inside the sealing member 130, that is, a substantial photoelectric conversion region.

In one embodiment, the grid pattern 113 functions as wires for withdrawing excited electrons generated as a result of photoelectric conversion, and in order to provide a low-resistance current path, the line width W or the pitch C of the finger electrodes 113a may be adjusted. That is, the width W and/or the pitch C of the grid pattern 113 may be appropriately designed in consideration of an opening ratio and an electrical resistance.

The opening region OP of the grid pattern 113 is a region that is exposed by the opaque grid pattern 113 and through which valid light is incident. The semiconductor layer 117 is formed in the opening region OP of the grid pattern 113. The semiconductor layer 117 or the photosensitive dye absorbed into the semiconductor layer 117 may generate excited electrons by receiving light incident through the opening region OP of the grid pattern 113.

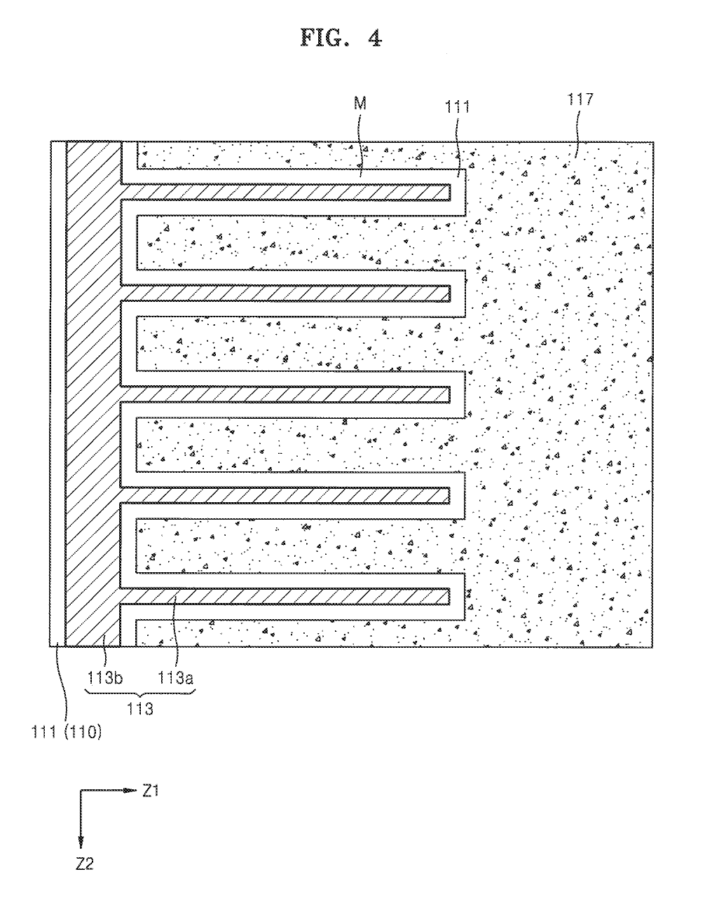

FIG. 4 is a top view showing the alignment of the grid pattern 113 and the semiconductor layer 117 illustrated in FIGS. 1 and 2. Referring to FIG. 4, the grid pattern 113 and the semiconductor layer 117 formed in the opening region OP of the grid pattern 113 may generally have overall comb shapes complementary to each other, and a margin region M is formed between the grid pattern 113 and the semiconductor layer 117.

As further described below, the grid pattern 113 and the semiconductor layer 117 are formed on the first substrate 110, and more particularly, on the transparent conductive film 111 of the first substrate 110. In one embodiment, the margin region M is ensured between the grid pattern 113 and the semiconductor layer 117 in consideration of an error of a patterning process. If the grid pattern 113 and the semiconductor layer 117 overlap each other, incident light may be blocked and thus the efficiency of photoelectric conversion may be reduced, and layers having different thermal behaviors (i.e. corresponding to the grid pattern 113 and the semiconductor layer 117) may interfere with each other and thus physical damage of the grid pattern 113 or the semiconductor layer 117 may be caused.

The transparent conductive film 111 is exposed by the margin region M between the grid pattern 113 and the semiconductor layer 117, and the conductive thin film 140 for supplementing the relatively low electrical conductivity of the transparent conductive film 111 is formed on the margin region M. In one embodiment, the conductive thin film 140 may be formed in a bent pattern along the margin region M between the grid pattern 113 and the semiconductor layer 117. However, the conductive thin film 140 is not limited to the bent pattern as long as an electrical conductivity is supplemented between the grid pattern 113 and the semiconductor layer 117.

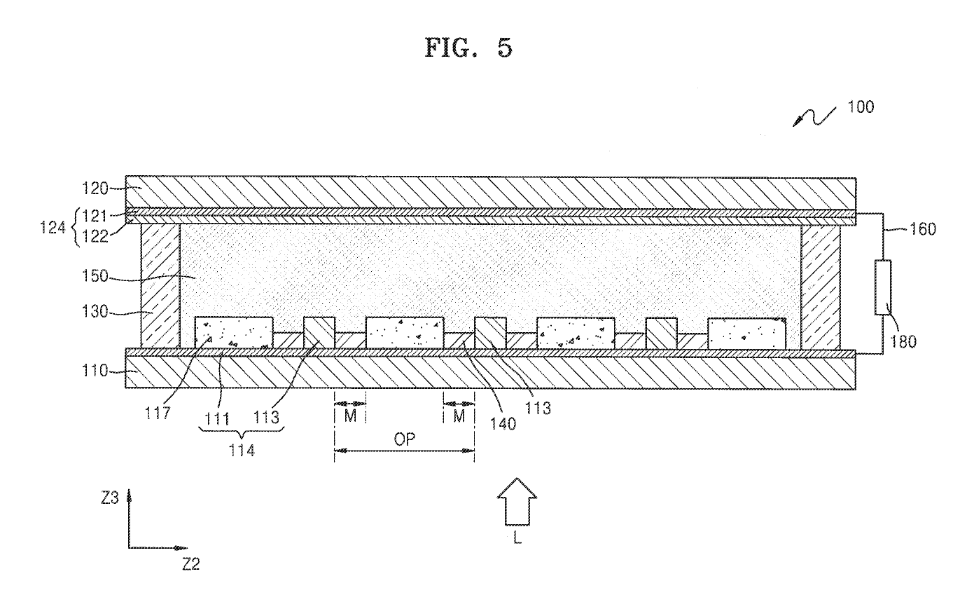

FIG. 5 is a cross-sectional view of the photoelectric conversion device 100, taken along the line V-V of FIG. 1. The photoelectric conversion device 100 may be formed by disposing the first and second substrates 110 and 120, on which function layers (i.e. the first electrode 114, the semiconductor layer 117, and the second electrode 124) for performing photoelectric conversion are formed, to face each other, disposing the sealing member 130 along the edges between the first and second substrates 110 and 120 so as to seal the first and second substrates 110 and 120, and injecting an electrolyte 150 into the photoelectric conversion device 100 through an electrolyte inlet (not shown).

In one embodiment, the first substrate 110 on which the first electrode 114 is formed and the second substrate 120 on which the second electrode 124 is formed are disposed to face each other, the semiconductor layer 117 into which a photosensitive dye for generating excited electrons by using light L is absorbed is formed on the first electrode 114, and the electrolyte 150 is filled between the semiconductor layer 117 and the second electrode 124.

The first and second electrodes 114 and 124 may be electrically connected by the wire 160 via an external circuit 180. However, in a modularized structure in which a plurality of photoelectric conversion devices 100 are connected in series or in parallel, the first and second electrodes 114 and 124 of the photoelectric conversion devices 100 may be connected in series or in parallel, and the first and second electrodes 114 and 124 at both ends of the modularized structure may be connected to the external circuit 180.

The first substrate 110 may be formed of a transparent material and may be formed as a light receiving substrate having a light incident surface. For example, the first substrate 110 may be formed as a glass substrate or a resin film. The resin film may be used, for example, when flexibility is required.

In one embodiment, the first electrode 114 may function as a negative electrode of the photoelectric conversion device 100. The first electrode 114 may provide a current path by receiving electrons generated due to photoelectric conversion. In one embodiment, a photosensitive dye is absorbed into the semiconductor layer 117, and the light L incident through the first electrode 114 functions as an excitation source of the photosensitive dye.

The first electrode 114, in one embodiment, includes the transparent conductive film 111 and the grid pattern 113 formed on the transparent conductive film 111. The transparent conductive film 111 may be formed of a transparent and electrically conductive material (e.g., a transparent conducting oxide (TCO) such as indium tin oxide (ITO), fluorine doped tin oxide (FTO), or antimony doped tin oxide (ATO).

The grid pattern 113, in one embodiment, reduces an electrical resistance of the first electrode 114, and functions as wires for providing a low-resistance current path by receiving electrons generated due to photoelectric conversion. For example, the grid pattern 113 may be formed of a metallic material having a relatively high electrical conductivity, such as gold (Au), silver (Ag), or aluminum (Al), for example, and may be patterned on the transparent conductive film 111. For example, the grid pattern 113 may be patterned on the transparent conductive film 111 in a stripe pattern extending along one direction, or in a mesh pattern by performing an appropriate patterning process such as vapor deposition.

In one embodiment, the grid pattern 113 is formed of an opaque material, such as a metallic material, and a light incident region is reduced by an area covered by the grid pattern 113. Accordingly, in one embodiment, an appropriate opening ratio may be achieved by adjusting the line width W and the pitch C (i.e. the distance between neighboring pattern lines) of the grid pattern 113.

The semiconductor layer 117, in one embodiment, is formed in the opening region OP exposed by the grid pattern 113, and the light L incident through the opening region OP of the grid pattern 113 functions as an excitation source of the photosensitive dye absorbed into the semiconductor layer 117.

In one embodiment, the semiconductor layer 117 may be formed of a metal oxide such as cadmium (Cd), zinc (Zn), indium (In), lead (Pb), molybdenum (Mo), tungsten (W), antimony (Sb), titanium (Ti), silver (Ag), manganese (Mn), tin (Sn), zirconium (Zr), strontium (Sr), gallium (Ga), silicon (Si), or chromium (Cr) oxide. The semiconductor layer 117 may increase the efficiency of photoelectric conversion by absorbing the photosensitive dye. In one embodiment, the semiconductor layer 117 may be formed by patterning a paste in which semiconductor particles having diameters of about 5 nm to about 1000 nm are dispersed, on the transparent conductive film 111 formed on the first substrate 110, and then heating or pressing the patterned paste by applying a suitable amount of heat or pressure.

In one embodiment, the photosensitive dye absorbed into the semiconductor layer 117 may absorb the light L incident through the opening region OP of the grid pattern 113, and electrons of the photosensitive dye may be excited from a base state to an excitation state, thereby forming a driving current.

The semiconductor layer 117 is formed on the transparent conductive film 111 in the opening region OP exposed by the grid pattern 113, and the conductive thin film 140 is formed between the semiconductor layer 117 and the grid pattern 113. The conductive thin film 140 may be formed on the transparent conductive film 111 between the semiconductor layer 117 and the grid pattern 113.

The conductive thin film 140 provides a low-resistance current path and improves the overall efficiency of photoelectric conversion by supplementing the electrical conductivity of the transparent conductive film 111 formed between the semiconductor layer 117 and the grid pattern 113.

The semiconductor layer 117 and the grid pattern 113 may be patterned together on the transparent conductive film 111 with the margin region M between the semiconductor layer 117 and the grid pattern 113 in consideration of a process error or tolerance. The semiconductor layer 117 and the grid pattern 113 may be definitely spaced apart from each other due to the margin region M. As such, the amount of the light L incident through the semiconductor layer 117 may be increased by preventing or substantially preventing the grid pattern 113 from blocking the light L, and physical damage such as cracks or corrosion caused when layers having different thermal behaviors (i.e. corresponding to the grid pattern 113 and the semiconductor layer 117) in a high-temperature environment of about 50° C. to about 80° C. are stacked on one another may be prevented or substantially prevented.

The conductive thin film 140 at the margin region M between the semiconductor layer 117 and the grid pattern 113 enhances the electrical conductivity of the transparent conductive film 111 and thus reduces the resistance of a current path formed on the first substrate 110.

In one embodiment, the conductive thin film 140 may be formed of a metallic material having a relatively high electrical conductivity and that does not react with the electrolyte 150 when contacting the electrolyte 150. In one embodiment, the conductive thin film 140 may be formed of a material including titanium (Ti). For example, the conductive thin film 140 may be patterned on the margin region M between the semiconductor layer 117 and the grid pattern 113 by vapor-depositing a material mainly including Ti. The conductive thin film 140 may be exposed to the electrolyte 150, but is not limited thereto.

If the conductive thin film 140 having a relatively high electrical conductivity is formed on the margin region M between the grid pattern 113 and the semiconductor layer 117, a relatively high electrical conductivity may be substantially obtained over an entire surface of the first substrate 110, the electrical resistance of a current path may be reduced, and the efficiency of photoelectric conversion may be increased.

In one embodiment, the grid pattern 113, the semiconductor layer 117 formed in the opening region OP of the grid pattern 113, and the conductive thin film 140 formed on the margin region M between the grid pattern 113 and the semiconductor layer 117 may cover the entire surface or substantially the entire surface of the first substrate 110 and may supplement the relatively low electrical conductivity of the transparent conductive film 111. The transparent conductive film 111 may have a relatively low electrical conductivity due to characteristics of a transparent material, and the grid pattern 113, the semiconductor layer 117, and the conductive thin film 140 may reduce the surface resistance of the first substrate 110 in association with the transparent conductive film 111.

In one embodiment, the photosensitive dye is absorbed into the semiconductor layer 117 and absorbs the light L incident through the first substrate 110, and electrons of the photosensitive dye are excited from a base state to an excitation state. The excited electrons move to a conduction band of the semiconductor layer 117 by using electrical connection between the photosensitive dye and the semiconductor layer 117, pass through the semiconductor layer 117 to reach the first electrode 114, and exit through the first electrode 114, thereby forming a driving current for driving the external circuit 180.

In one embodiment, the photosensitive dye absorbed into the semiconductor layer 117 may be formed as molecules for absorbing visible light and rapidly allowing electrons to move toward the semiconductor layer 117 in an excited state due to the light L. The photosensitive dye may be in the form of a liquid, a gel that is a half-solid, or a solid. For example, the photosensitive dye absorbed into the semiconductor layer 117 may be a ruthenium (Ru)-based photosensitive dye. For example, a predetermined photosensitive dye may be absorbed into the semiconductor layer 117 by dipping the first substrate 110 on which the semiconductor layer 117 is formed into a solution including the photosensitive dye.

The electrolyte 150 may be a redox electrolyte including an oxidant and reductant pair and may be in the form of a solid, a gel, or a liquid.

In one embodiment, the second substrate 120 disposed to face the first substrate 110 does not particularly require transparency. However, in order to increase the efficiency of photoelectric conversion, the second substrate 120 may be formed of a transparent material so that the light L is received into the photoelectric conversion device 100 from two sides and, in one embodiment, may be formed of the same material as the first substrate 110.

The second electrode 124 may include a transparent conductive film 121 and a catalyst layer 122 formed on the transparent conductive film 121. The transparent conductive film 121 may be formed of a transparent and electrically conductive material (e.g., a transparent conducting oxide (TCO), such as indium tin oxide (ITO), fluorine doped tin oxide (FTO), or antimony doped tin oxide (ATO)). The catalyst layer 122 may be formed of a material functioning as a reduction catalyst for providing electrons to the electrolyte 150 (e.g., a metal such as platinum (Pt), gold (Au), silver (Ag), copper (Cu), or aluminum (Al), a metal oxide such as tin oxide (SnO), or a carbon (C)-based material such as graphite).

The second electrode 124, in one embodiment, functions as a positive electrode of the photoelectric conversion device 100 and functions as a reduction catalyst for providing electrons to the electrolyte 150. The photosensitive dye absorbed into the semiconductor layer 117 absorbs the light L so as to generate excited electrons, and the excited electrons exit through the first electrode 114. The photosensitive dye having lost electrons is reduced by receiving electrons provided when the electrolyte 150 is oxidized, and the electrolyte 150 is reduced due to electrons that reach the second electrode 124 via the external circuit 180, thereby completing an operation of the photoelectric conversion device 100.

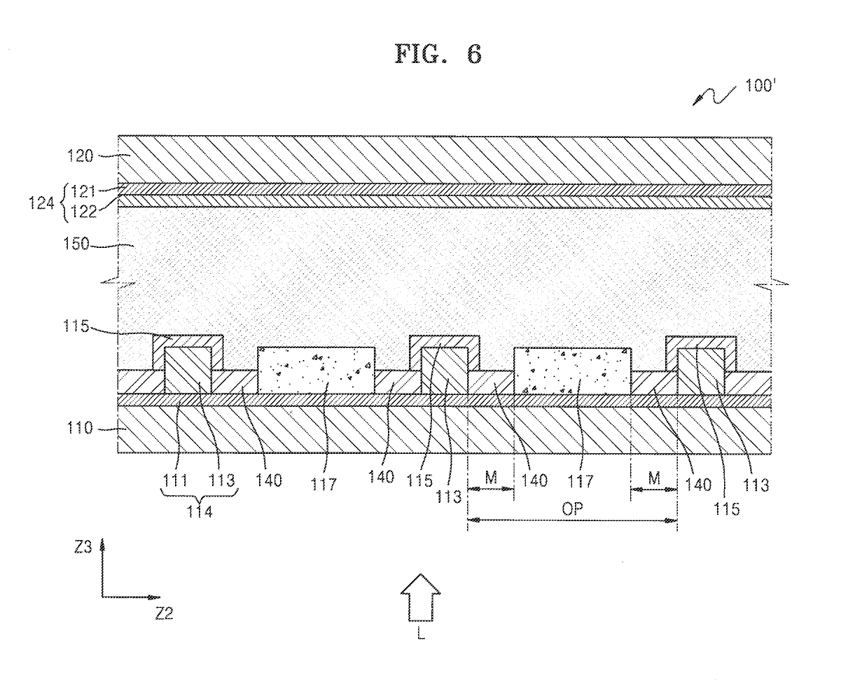

FIG. 6 is a cross-sectional view of a photoelectric conversion device 100′ according to another embodiment of the present invention. The photoelectric conversion device 100′ is similar to the photoelectric conversion device 100 described above except that, referring to FIG. 6, a protective layer 115 may be further formed on an outer surface of the grid pattern 113. The protective layer 115 prevents or substantially prevents the grid pattern 113 from contacting and reacting with the electrolyte 150 and thus prevents or substantially prevents damage (e.g., corrosion) of the grid pattern 113. The protective layer 115 may be formed of a material that does not react with the electrolyte 150, such as a curable resin, for example.

The protective layer 115, in one embodiment, may be formed on the grid pattern 113 by coating a paste (not shown) on the grid pattern 113 by using a pattern mask (not shown), and then curing the coated paste. In one embodiment, for example, the protective layer 115 may surround the outer surface of the grid pattern 113 and may have a line width greater than that of the grid pattern 113, so as to bury or cover the grid pattern 113.

The protective layer 115 for burying the grid pattern 113 may extend to contact the conductive thin film 140. For example, the protective layer 115 formed on the grid pattern 113 may cover an upper surface of the grid pattern 113 and may extend to side surfaces of the grid pattern 113 to contact and form an interface with the conductive thin film 140. In one embodiment, air-tight contact is formed between the conductive thin film 140 and the protective layer 115, and penetration of the electrolyte 150 and corrosion of the grid pattern 113 may thereby be prevented or substantially prevented.

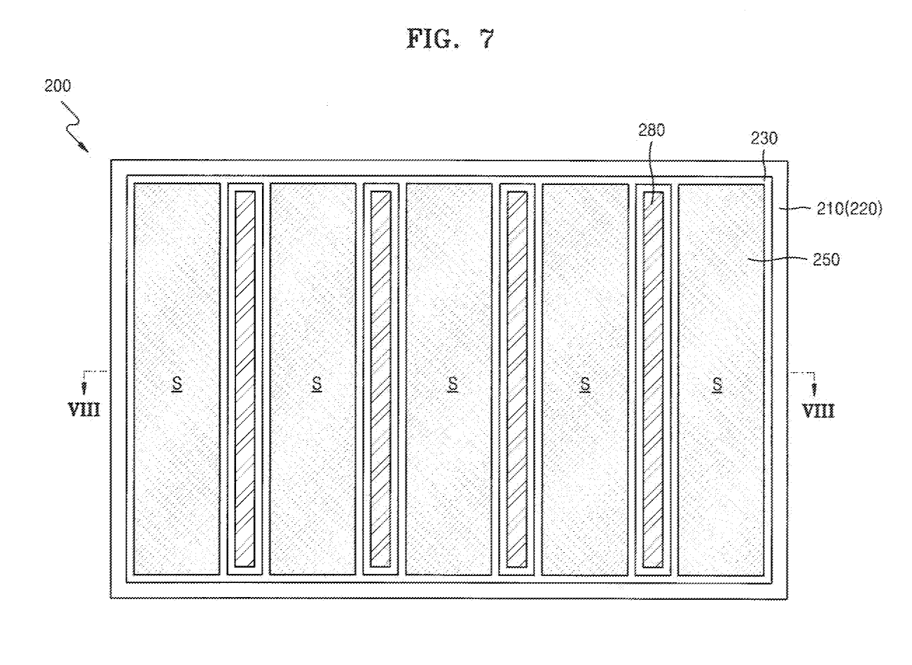

FIG. 7 is a top view of a photoelectric conversion device 200 according to another embodiment of the present invention. In FIG. 7, inner portions of the photoelectric conversion device 200 are shown through the second substrate 220 for purposes of illustration. Referring to FIG. 7, the photoelectric conversion device 200 includes a plurality of photoelectric cells S that are partitioned by sealing members 230.

Connection members 280 may be disposed between neighboring photoelectric cells S, and more particularly, between neighboring sealing members 230. The connection members 280 electrically modularize the photoelectric cells S by electrically connecting neighboring photoelectric cells S. For example, the photoelectric cells S may be connected to each other in series or in parallel by the connection members 280 and may be physically supported between first and second substrates 210 and 220, thereby forming modules.

An electrolyte 250 is filled in the photoelectric cells S and is sealed by the sealing members 230 disposed along edges of the photoelectric cells S. The sealing members 230 are formed around the electrolyte 250 so as to surround the electrolyte 250, and seal the electrolyte 250 such that the electrolyte 250 does not leak externally.

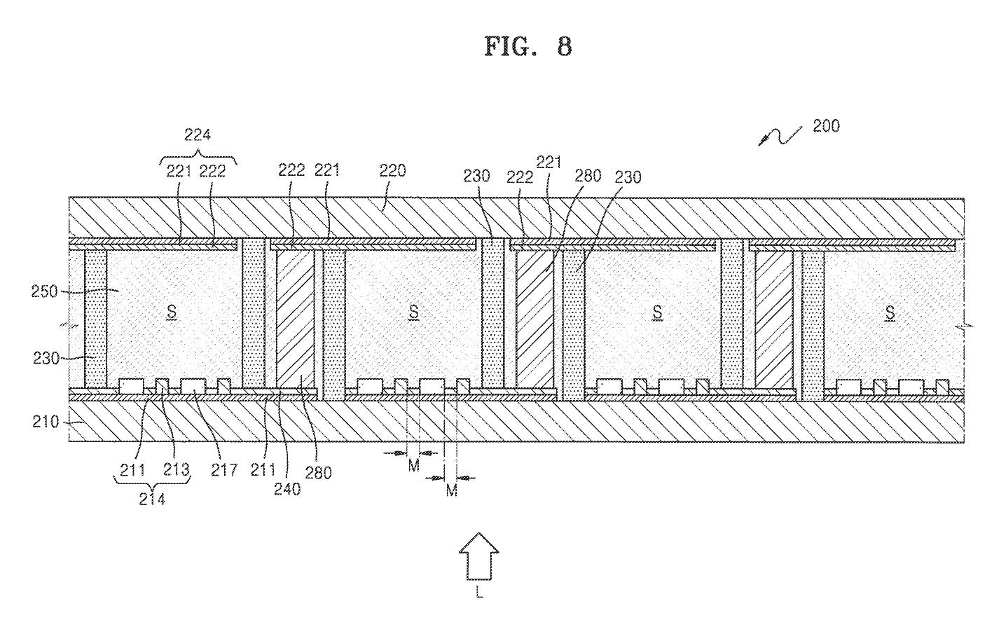

FIG. 8 is a cross-sectional view of the photoelectric conversion device 200, taken along the line VIII-VIII of FIG. 7. Referring to FIG. 8, the first and second substrates 210 and 220 on which first and second electrodes 214 and 224 are respectively formed are disposed to face each other, and the photoelectric cells S partitioned by the sealing members 230 are formed between the first and second substrates 210 and 220. The connection members 280 are formed between neighboring photoelectric cells S so as to connect the photoelectric cells S to each other, such as in series, for example.

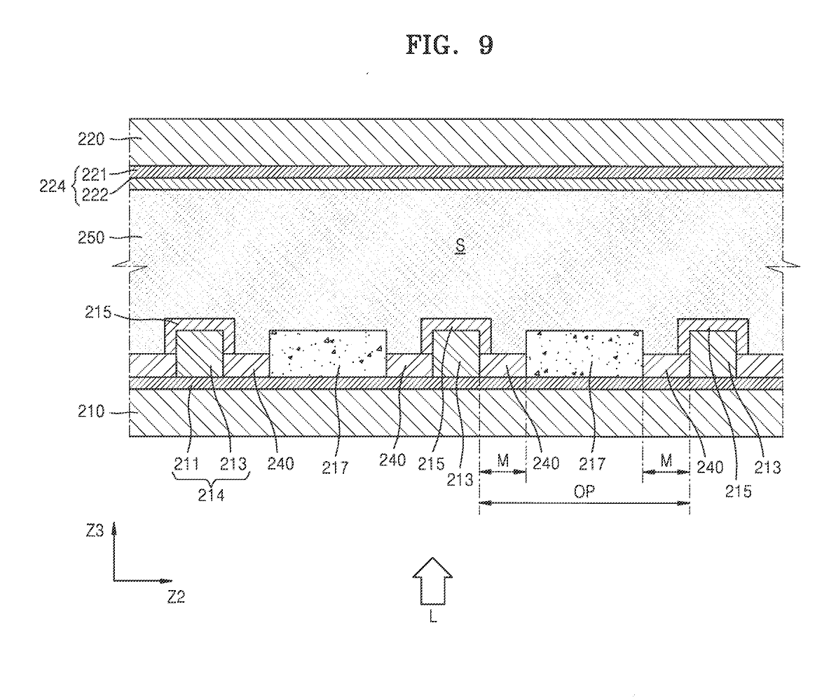

FIG. 9 is a enlarged view of a region of the cross-sectional view of FIG. 8. The photoelectric cells S include the first and second electrodes 214 and 224 respectively formed on the first and second substrates 210 and 220 disposed to face each other, a semiconductor layer 217 formed in an opening region OP exposed by a grid pattern 213 of the first electrode 214, and a conductive thin film 240 formed on a margin region M between the grid pattern 213 and the semiconductor layer 217. The electrolyte 250 in the photoelectric cells S is sealed by the sealing member 230 which also partitions the photoelectric cells S.

The opening region OP of the grid pattern 213 may refer to an incident region capable of receiving valid light L from the first substrate 210 and a region exposed by the grid pattern 213. In one embodiment, the first electrode 214 includes a transparent conductive film 211 and the grid pattern 213 formed on the transparent conductive film 211. The grid pattern 213 may be formed of an opaque metallic material in order to supplement a relatively low electrical conductivity of the transparent conductive film 211, and the semiconductor layer 217 may be patterned in the opening region OP exposed by the grid pattern 213. In one embodiment, a photosensitive dye absorbed into the semiconductor layer 217 generates excited electrons by using the light L incident through the opening region OP of the grid pattern 213 as an excitation source, and the excited electrons of the photosensitive dye form a driving current.

The grid pattern 213 and the semiconductor layer 217 are patterned on the transparent conductive film 211 with the margin region M between the grid pattern 213 and the semiconductor layer 217 in consideration of an error of a patterning process. In one embodiment, the conductive thin film 240 for supplementing the relatively low electrical conductivity of the transparent conductive film 211 and providing a low-resistance current path is formed on the margin region M.

The grid pattern 213, the semiconductor layer 217 formed in the opening region OP of the grid pattern 213, and the conductive thin film 240 formed on the margin region M between the grid pattern 213 and the semiconductor layer 217 may cover an entire surface or substantially an entire surface of the photoelectric cells S and may form a low-resistance current path on the first substrate 210 together with the transparent conductive film 211, thereby improving the efficiency of photoelectric conversion.

In one embodiment, a protective layer 215 may be formed on an outer surface of the grid pattern 213. The protective layer 215 prevents or substantially prevents the grid pattern 213 from contacting and reacting with the electrolyte 250 and thus prevents or substantially prevents damage (e.g., corrosion) of the grid pattern 213.

In one embodiment, the second electrode 224 disposed to face the first electrode 214 may include a transparent conductive film 221 formed on the second substrate 220, and a catalyst layer 222 formed on the transparent conductive film 221.

Referring to FIG. 8, the sealing members 230 for sealing the electrolyte 250 contained in the photoelectric cells S are disposed between neighboring photoelectric cells S. The connection members 280 for electrically connecting neighboring photoelectric cells S are disposed adjacent to the sealing members 230. In one embodiment, the connection members 280 are formed between neighboring sealing members 230.

In one embodiment, the connection members 280 vertically extend to contact the conductive thin film 240 and the catalyst layer 222 disposed on and under the connection members 280 and thereby electrically connect the first and second electrodes 214 and 224 of neighboring photoelectric cells S to each other in series.

In one embodiment, each of the connection members 280 may connect the conductive thin film 240 extending from one photoelectric cell S along the first substrate 210 to the catalyst layer 222 extending from a neighboring photoelectric cell S along the second substrate 220, and may electrically connect the first and second electrodes 214 and 224 of neighboring photoelectric cells S via the conductive thin film 240 and the catalyst layer 222.

The conductive thin film 240, in one embodiment, reduces the connection resistance between the photoelectric cells S connected via the connection members 280. For example, the transparent conductive film 211 may have a relatively low electrical conductivity due to characteristics of a transparent material. The conductive thin film 240 may reduce the connection resistance between the photoelectric cells S and improve the overall efficiency of photoelectric conversion by supplementing the electrical conductivity of the transparent conductive film 211.

In one embodiment, the conductive thin film 240 is formed on the transparent conductive film 211, is supported by the first substrate 210, and extends from inside the photoelectric cells S toward the connection members 280. The connection members 280 may vertically extend between the conductive thin film 240 and the catalyst layer 222 respectively supported by the first and second substrates 210 and 220 so as to contact and connect the conductive thin film 240 and the catalyst layer 222.

The conductive thin film 240 may be integrally formed and patterned inside and outside the photoelectric cells S. That is, in one embodiment, the conductive thin film 240 may be formed (e.g., simultaneously formed) both inside the photoelectric cells S (i.e. on the margin region M between the grid pattern 213 and the semiconductor layer 217) and outside the photoelectric cells S (i.e. from inside the photoelectric cells S toward the connection members 280) by using a same material and by performing a same patterning process. In one embodiment, the conductive thin film 240 may be formed of a metallic material having a relatively high electrical conductivity and may include titanium (Ti) to not react with the electrolyte 250 when contacting the electrolyte 250. The conductive thin film 240 may be patterned on the transparent conductive film 211 by using any of various suitable patterning processes, such as vapor deposition.

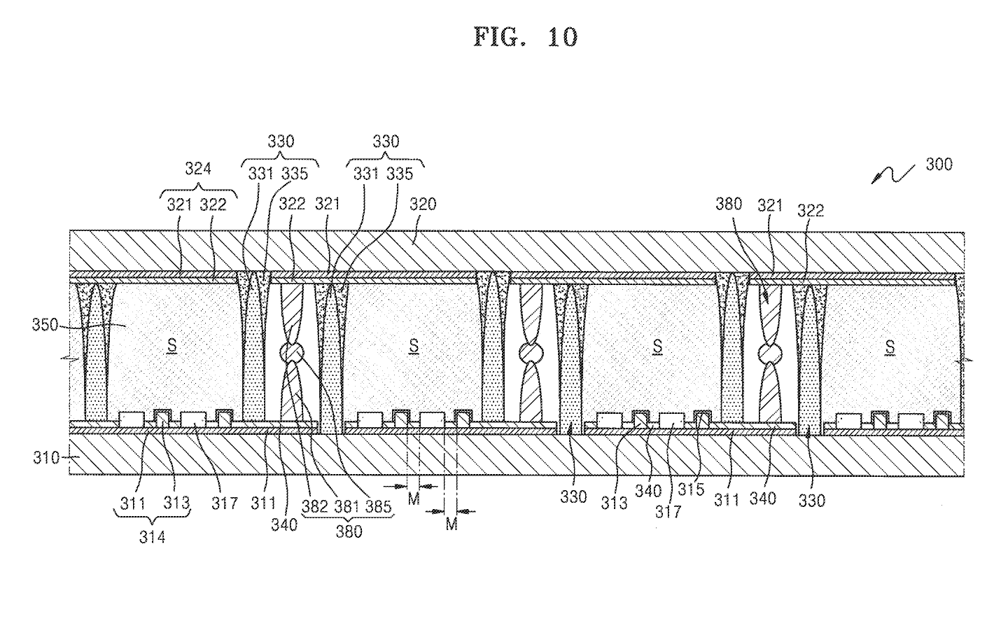

FIG. 10 is a cross-sectional view of a photoelectric conversion device 300 according to another embodiment of the present invention. Referring to FIG. 10, first and second substrates 310 and 320 on which first and second electrodes 314 and 324 are respectively formed are disposed to face each other, and sealing members 330 for partitioning a plurality of photoelectric cells S, and connection members 380 for electrically connecting neighboring photoelectric cells S are disposed between the first and second substrates 310 and 320.

In one embodiment, each of the sealing members 330 may include a spacer 331 and a sealant 335 formed to surround at least a portion of the spacer 331. In one embodiment, the spacer 331 maintains a constant distance between the first and second substrates 310 and 320. For example, a cell gap of the photoelectric cells S aligned between the first and second substrates 310 and 320 may be controlled by controlling a height of the spacers 331. The spacer 331, in one embodiment, may be formed of glass frit, and the cell gap may be minutely and easily controlled by controlling the height of glass frit.

The sealant 335 may be coated on the spacer 331 so as to surround at least a portion of the spacer 331. For example, the spacer 331 may be formed to extend from the first substrate 310 toward the second substrate 320, and the sealant 335 may be formed on an end portion of the spacer 331 proximate to the second substrate 320 so as to achieve an air-tight contact between the spacer 331 and the second substrate 320.

The sealant 335, in one embodiment, may be formed of a resin-based material, and more particularly, of a thermosetting resin and/or a photocurable resin. For example, the sealant 335 may be formed of a ultraviolet (UV)-curable material and may be cured by irradiating UV light and applying a low-temperature heat, for example. Due to the low-temperature curing, other function layers of the photoelectric conversion device 300 (i.e. the first electrode 314, a semiconductor layer 317, and the second electrode 324) may be prevented or substantially prevented from deteriorating, as may occur in a high-temperature environment.

The connection members 380 for electrically connecting neighboring photoelectric cells S are disposed adjacent to the sealing members 330. In one embodiment, the connection members 380 may be formed between neighboring sealing members 330.

In one embodiment, the connection members 380 may vertically extend to contact a conductive thin film 340 and a catalyst layer 322 disposed on and under the connection members 380 and thus may electrically connect the first and second electrodes 314 and 324 of neighboring photoelectric cells S to each other.

In one embodiment, each of the connection members 380 may include first and second conductive bumps 381 and 382 respectively formed on the first and second substrates 310 and 320, and a flexible conductor 385 for connecting the first and second conductive bumps 381 and 382 to each other. The first and second conductive bumps 381 and 382 protrude to face each other and are electrically connected to each other by disposing the flexible conductor 385 therebetween. The first and second conductive bumps 381 and 382 may be formed of a metallic component having a relatively high electrical conductivity, such as a silver (Ag) component, for example.

The first and second substrates 310 and 320 on which the first and second conductive bumps 381 and 382 are respectively formed may be bonded to each other to face each other, and the first and second conductive bumps 381 and 382 may be electrically connected to each other by disposing the flexible conductor 385 therebetween. The flexible conductor 385 may be disposed between the first and second conductive bumps 381 and 382, and may be flexibly deformed and pressed onto the first and second conductive bumps 381 and 382 when a bonding pressure is applied, thereby achieving firm conductive coupling. For example, the flexible conductor 385 may be formed of an Ag component mixed with a flexible component (not shown) so as to have sufficient flexibility to accommodate the first and second conductive bumps 381 and 382 when a compression pressure is applied, and may be cured by performing an appropriate curing process after the first and second conductive bumps 381 and 382 are connected via the flexible conductor 385.

In one embodiment, the connection members 380 vertically extend to contact the conductive thin film 340 and the catalyst layer 322 disposed on and under the connection members 380 and electrically connect the first and second electrodes 314 and 324 of neighboring photoelectric cells S to each other, such as in series, for example.

In one embodiment, each of the connection members 380 connects the conductive thin film 340 extending from one photoelectric cell S along the first substrate 310 to the catalyst layer 322 extending from a neighboring photoelectric cell S along the second substrate 320, and may thereby electrically connect the first and second electrodes 314 and 324 of neighboring photoelectric cells S via the conductive thin film 340 and the catalyst layer 322.

The conductive thin film 340 may reduce the connection resistance between the photoelectric cells S connected via the connection members 380, and, in one embodiment, may be integrally formed inside and outside the photoelectric cells S.

Referring to FIG. 10, the first electrode 314 formed on the first substrate 310 may include a transparent conductive film 311 and a grid pattern 313 formed on the transparent conductive film 311, and the semiconductor layer 317 may be formed in an opening region exposed by the grid pattern 313. The conductive thin film 340 may be formed between the grid pattern 313 and the semiconductor layer 317. In one embodiment, a protective layer 315 may be formed on an outer surface of the grid pattern 313. The second electrode 324 formed on the second substrate 320 may include a transparent conductive film 321 and the catalyst layer 322 formed on the transparent conductive film 321.

As described above, a photoelectric conversion device according to embodiments of the present invention form a low-resistance current path and improve the overall efficiency of photoelectric conversion by forming a conductive thin film at a margin region between different function layers patterned adjacent to each other.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof. Descriptions of features or aspects within each embodiment should typically be considered as available for other similar features or aspects in other embodiments.

What is claimed is:

1. A photoelectric conversion device comprising:
a first substrate;
a first electrode on the first substrate and comprising a grid pattern;
a second substrate facing the first substrate;
a second electrode on the second substrate;
a semiconductor layer on the first substrate at an opening region of the grid pattern; and
a conductive thin film on the first substrate between the grid pattern and the semiconductor layer.

2. The photoelectric conversion device of claim 1, wherein the first electrode further comprises a transparent conductive film between the first substrate and the grid pattern.

3. The photoelectric conversion device of claim 2, wherein the grid pattern, the semiconductor layer, and the conductive thin film are formed together on the transparent conductive film.

4. The photoelectric conversion device of claim 1, further comprising a protective layer covering an outer surface of the grid pattern.

5. The photoelectric conversion device of claim 4, wherein the protective layer covers the grid pattern so as to contact the conductive thin film.

6. The photoelectric conversion device of claim 1, wherein the grid pattern comprises:
a plurality of finger electrodes extending in parallel along a first direction; and
a collecting electrode extending in a second direction crossing the first direction and interconnecting end portions of the finger electrodes.

7. The photoelectric conversion device of claim 6, wherein the grid pattern has a comb shape in which the finger electrodes protrude from the collecting electrode at substantially equal intervals along the second direction.

8. The photoelectric conversion device of claim 6, wherein the conductive thin film extends in a repeated bent pattern along the finger electrodes and the collecting electrode.

9. The photoelectric conversion device of claim 6,
wherein the grid pattern has a comb shape in which the finger electrodes protrude from the collecting electrode at substantially equal intervals along the second direction, and
wherein the semiconductor layer has a comb shape that is complementary to the comb shape of the grid pattern.

10. The photoelectric conversion device of claim 1, wherein the conductive thin film comprises titanium (Ti).

11. The photoelectric conversion device of claim 1, further comprising:
an electrolyte between the first and second substrates; and
sealing members extending to surround the electrolyte between the first and second substrates.

12. The photoelectric conversion device of claim 11,
wherein the sealing members partition a plurality of photoelectric cells between the first and second substrates, and
wherein the photoelectric conversion device further comprises a connection member between the sealing members and electrically connecting neighboring photoelectric cells of the plurality of photoelectric cells to each other,

13. The photoelectric conversion device of claim 12, wherein the conductive thin film extends toward the connection member.

14. The photoelectric conversion device of claim 12, wherein the conductive thin film between the grid pattern and the semiconductor layer extends toward and contacts the connection member.

15. A photoelectric conversion device comprising:
first and second substrates facing each other;
sealing members partitioning a plurality of photoelectric cells between the first and second substrates; and
a connection member between neighboring sealing members and electrically connecting neighboring photoelectric cells of the plurality of photoelectric cells to each other,
wherein each of the plurality of photoelectric cells comprises:
a first electrode on the first substrate and comprising a grid pattern;
a second electrode on the second substrate;
a semiconductor layer on the first substrate at an opening region of the grid pattern; and
a conductive thin film on the first substrate between the grid pattern and the semiconductor layer, and
wherein the conductive thin film extends toward and contacts the connection member.

16. The photoelectric conversion device of claim 15, wherein each of the sealing members comprises:
a spacer on at least one of the first substrate or the second substrate; and
a sealant surrounding at least a portion of the spacer.

17. The photoelectric conversion device of claim 15, wherein the connection member comprises:
first and second conductive bumps respectively formed on the first and second substrates; and
a flexible conductor connecting the first and second conductive bumps.
